(19) United States
(12) Patent Application Publication
(10) Pub. No.: US 2007/0166958 A1
(43) Pub. Date: Jul. 19, 2007

(54) METHOD OF WAFER LEVEL PACKAGING AND CUTTING

(76) Inventor: Shun-Ta Wang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/427,343

(22) Filed: Jun. 29, 2006

(30) Foreign Application Priority Data
Jan. 18, 2006 (TW) 095101917

(51) Int. Cl. H01L 21/00

(52) U.S. Cl. 438/460; 257/E21.238

(57) ABSTRACT

A packaging wafer having a plurality of cavities on an upper surface thereof is provided. A plurality of trenches is formed between the cavities, wherein the packaging wafer has a thickness greater than a depth of the trenches. The packaging wafer is bonded to an element wafer and a hermetical window is formed from each cavity. Then, a cutting process is performed and an unbound part of the packaging wafer is removed. Therefore, a wafer level package is formed. Finally, the wafer level package is divided into a plurality of individual packages.

### BACKGROUND OF THE INVENTION

1. Field of the Invention

The invention relates to a method of packaging and cutting, and more particularly, to a method of wafer level packaging and cutting.

2. Description of the Prior Art

A packaging process of semiconductor devices is an important step in back-end stages of semiconductor device manufacture. Packaging provides the semiconductor device with protection, heat dissipation, electricity, or connection to other components for compatibility with next level assembly. Please refer to FIG. 1 through FIG. 4. FIG. 1 through FIG. 4 illustrate a conventional method of die packaging. As shown in FIG. 1, a wafer 10 having a plurality of devices 12 on an upper surface thereof is provided. The wafer 10 is divided into a plurality of dies 16 for subsequent packaging. As shown in FIG. 2, a cap wafer 20 is provided. The cap wafer 20 is cut into a plurality of packaging caps 22 that have proper size and shape corresponding to the die 16. As shown in FIG. 3, a binder 30, such as a polymer glue is smeared on the upper surface of the die 16. Finally, the packaging cap 22 is laid over the binder 30 on the upper surface of the die 16 and is bonded to form a package 40.

The conventional packaging method means that the wafer is divided into individual dies and then bonded to a cap to form a package. This packaging method needs individual operation, and even manual operation. In addition, these products may be contaminated or damaged during the following cutting process. This may reduce the yield and increase the cost and process time.

### SUMMARY OF THE INVENTION

It is therefore a primary objective of the invention to provide a method of wafer level packaging and cutting to improve the yield and reliability of the packaging process.

According to the invention, a method of wafer level packaging and cutting is provided. At first, a packaging wafer comprising a plurality of cavities on an upper surface thereof is provided. A pre-cutting process is performed upon the upper surface of the packaging wafer. A plurality of trenches is formed between the cavities, and a plurality of partitions is formed between the cavities and the trenches. In addition, the packaging wafer has a thickness greater than a depth of the trenches. Moreover, an element wafer is provided. The element wafer has a plurality of devices and a plurality of bonding pads on a surface thereof. Thereafter, the partitions of the packaging wafer are bonded to the element wafer. Afterwards, a cutting process is performed along the trenches on a lower surface of the packaging wafer, and then an unbound part of the packaging wafer is removed to expose the bonding pads of the element wafer. Consequently, a wafer level package is formed, and a wafer level testing can be performed thereon.

The method of the invention may simplify the cutting process and diminish damage and contamination resulting from the cutting process. The method may apply to electronic device packages, micro-electromechanical systems (MEMS) device packages, and optical device packages. In addition, the method of the invention reduces the yield loss caused by following processes, such as cutting, breaking, and cleaning. Furthermore, the method is compatible to general semiconductor manufacturing processes, and may apply to batch production. The method also has advantages of high yield and simplified testing, and has the ability to overcome the difficulties of the conventional techniques.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 4 illustrate a conventional method of die packaging.

FIG. 5 through FIG. 11 are schematic diagrams illustrating a method of wafer level packaging and cutting according to a preferred embodiment of the invention.

FIG. 12 illustrates another bonding method of the packaging wafer and the element wafer according to another preferred embodiment of the invention.

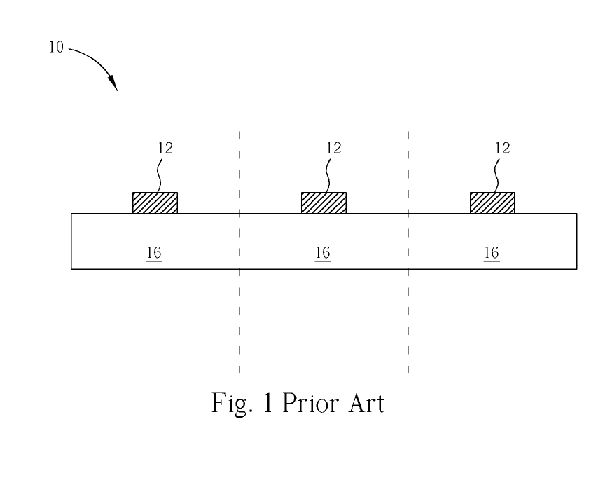

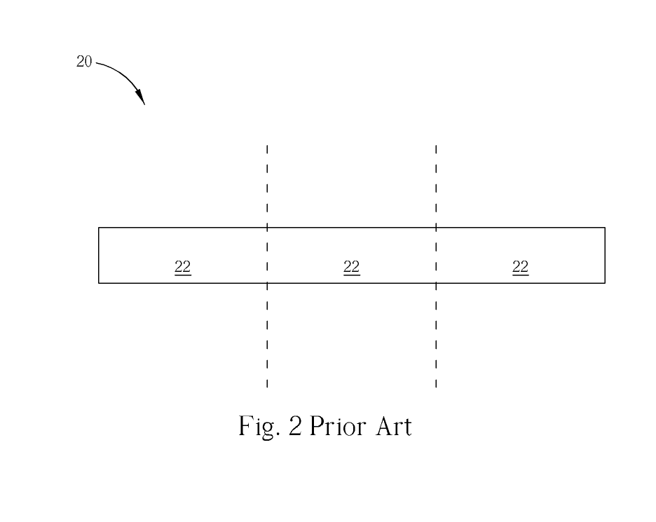

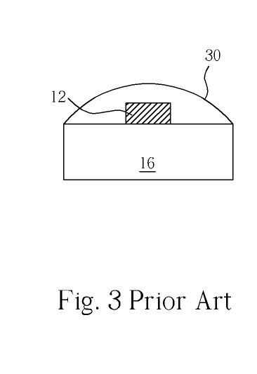

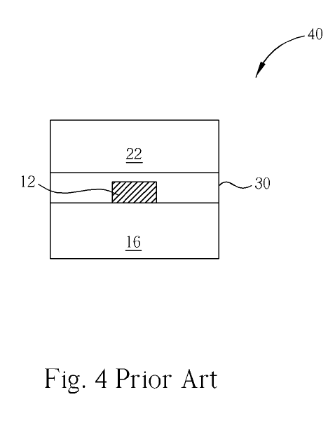

### DETAILED DESCRIPTION

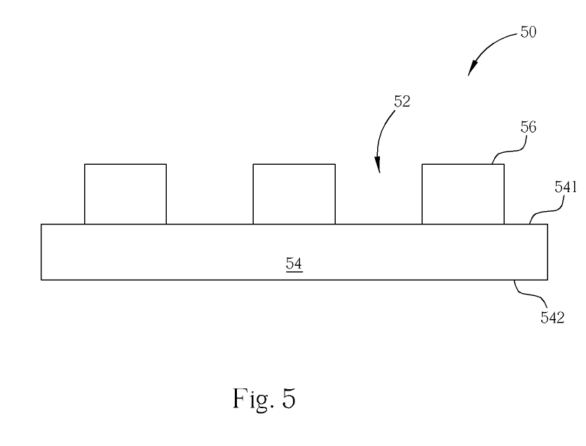

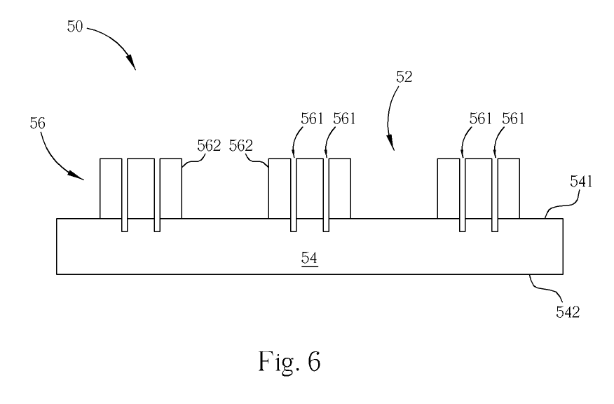

Hereinafter, an embodiment of the present invention will be described in detail with reference to the drawings. Please refer to FIG. 5 through FIG. 11. FIG. 5 through FIG. 11 are schematic diagrams illustrating a method of wafer level packaging and cutting according to a preferred embodiment of the invention. As shown in FIG. 5, a packaging wafer 50 is provided. The packaging wafer 50 comprises a transparent substrate 54 and a pattern 56, such as a silicon pattern, disposed on an upper surface 541 thereof. The pattern 56 defines a plurality of cavities 52 on the upper surface 541 of the packaging wafer 50. The above-mentioned transparent substrate 54 may comprise glass, quartz, or light transmissible plastic. In this preferred embodiment, the transparent substrate 54 is a glass substrate. As shown in FIG. 6, a pre-cutting process is performed upon a predetermined position of the packaging wafer 50. The pre-cutting process may be a wet wafer-cutting process, such as a wet etching process, or a dry wafer-cutting process, such as a dry etching process or cutting by a blade. The pre-cutting process forms a plurality of trenches 561 and thereby forms a plurality of partitions 562 between the trenches 561 and the cavities 52. The trenches 561 pass through the wafer 56 and reach the transparent substrate 54. However, the trenches 561 do not penetrate the transparent substrate 54. In this preferred embodiment, the trenches 561 have tracks about 100 micrometer (μm) in depth on the transparent substrate 54, and other depths are allowable. The depth of the trenches 561 may be adjusted depending on the thickness of the transparent substrate 54.

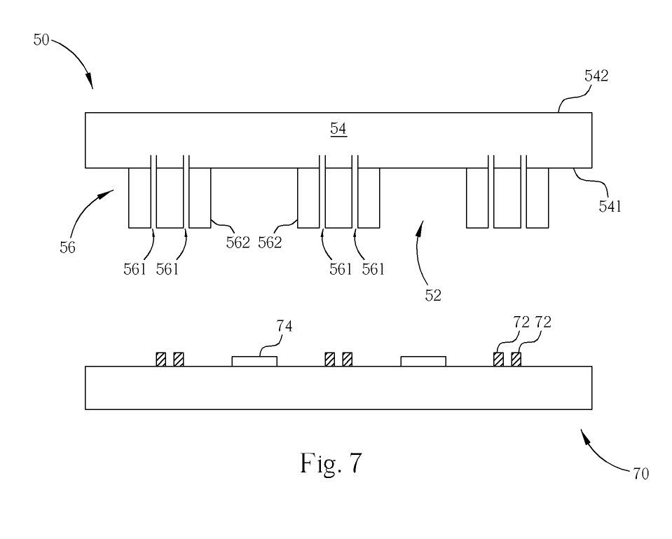

As shown in FIG. 7, an element wafer 70 is provided. The element wafer 70 has a plurality of bonding pads 72 and a plurality of devices 74 disposed on a surface of the element wafer 70. The devices 74 may be electronic devices, MEMS devices, or optical devices. In this preferred embodiment, the devices 74 are image sensor devices. Afterwards, the packaging wafer 50 is aligned with the element wafer 70, and the cavities 52 of the packaging wafer 50 corresponded to the devices 74 of the element wafer 70.

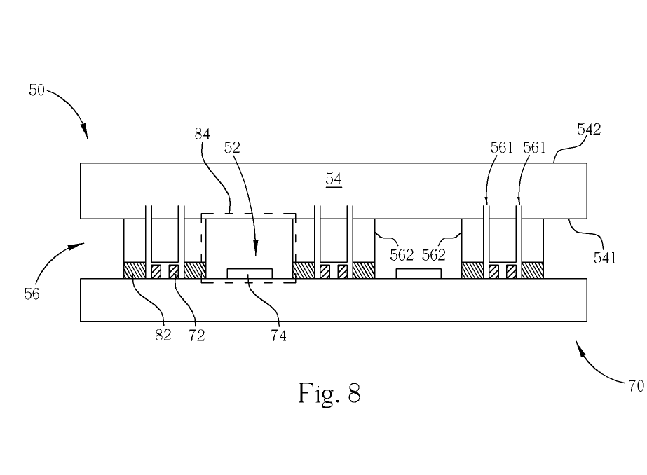

Please refer to FIG. 8. A binder 82, such as a polymer glue or a glass frit is formed by halftone printing or coating either on the end of the partitions 562 or on the surface of the element wafer 70 at the position corresponding to the partition 562. Thereafter, a hermetic bonding process is performed. The cavities 52 of the packaging wafer 50 are bonded to the element wafer 70, and a plurality of hermetic windows 84 are formed. The hermetic windows 84 protect the devices 74 from the damage or contamination resulting from the following cutting process or cleaning process. In addition, the hermetic windows 84 ensure the devices 74 operate well.

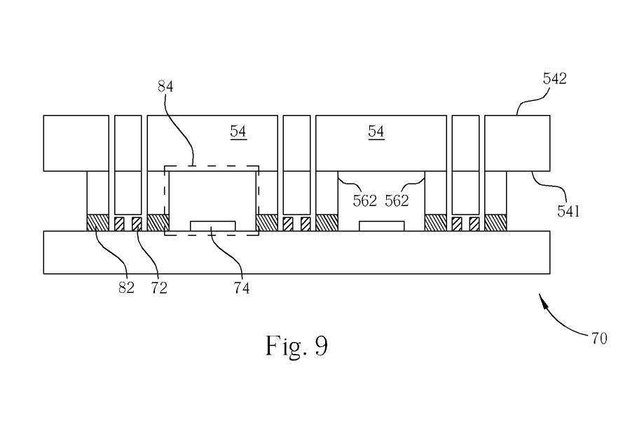

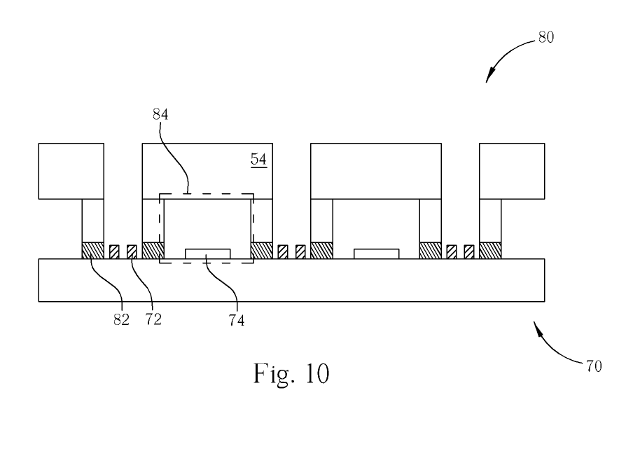

As shown in FIG. 9, a cutting process is performed on the packaging wafer 50 along the trenches 561. Because the trenches 561 reach the transparent substrate 54, the cutting process is performed upon a lower surface 542 of the packaging wafer 50 along the track of the trenches 561. The cutting process penetrates the packaging wafer 50 easily without damaging the element wafer 70 or the devices 74, which are protected by the hermetic windows 84. Please refer to FIG. 10. An unbound part of the packaging wafer 50 is removed to expose the bonding pads 72. Therefore, a wafer level package 80 is formed. In addition, the wafer level package 80 may undergo a wafer level testing immediately.

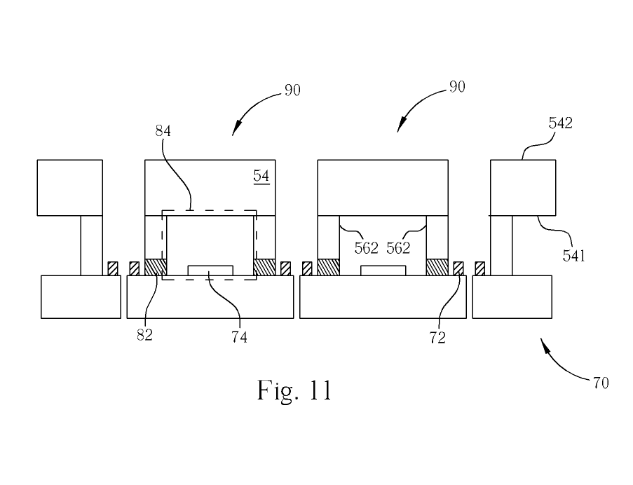

As shown in FIG. 11, the wafer level package 80 is divided into a plurality of individual packages 90 after the wafer level testing. These individual packages 90 may further apply to consumer electronics of smaller size.

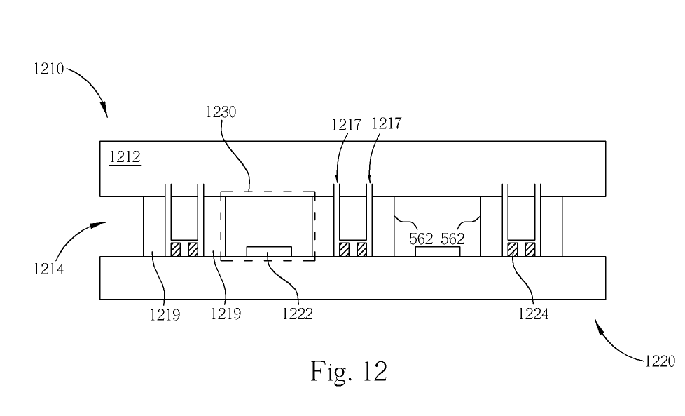

The package wafer may be bonded to the element wafer in other way. Please refer to FIG. 12. FIG. 12 illustrates another bonding method of the packaging wafer and the element wafer according to another preferred embodiment of the invention. As shown in FIG. 12, an element wafer 1220 and a packaging wafer 1210 are provided. The element wafer 1220 includes a plurality of devices 1222 and a plurality of bonding pads 1224 on the surface thereof. The packaging wafer 1210 comprises a transparent substrate 1212, a pattern 1214, and a plurality of cavities (not shown) defined by the pattern 1214 on the front surface of the packaging wafer 1210, wherein each pattern 1214 has a notch in the center. A pre-cutting process is performed on the front surface of the packaging wafer 1210. Therefore, a plurality of trenches 1217 and a plurality of partitions 1219 are formed. Due to each pattern 1214 having a notch in the center, the partitions 1219 have a thickness greater than that of the center of the pattern 1214. In addition, the trenches 1217 pass through the pattern 1214 and reach the transparent substrate 1212. The trenches 1217 have tracks about 100 μm in depth on the transparent substrate 1212. The depth of the tracks may be adjusted depending on requirements. Thereon, the packaging wafer 1210 is aligned with the element wafer 1220, and the cavities of the packaging wafer 1210 are corresponding to the devices 1222 of the element wafer 1220. Hermetic bonding is performed between the packaging wafer 1210 and the element wafer 1220. Since the depth of the partitions 1219 is greater than that of the center of the pattern 1214, the bonding of wafers may use non-intermediate layer bonding in addition to a binder, such as anodic bonding or fusion bonding. The partitions 1219 bond to the element wafer 1220 directly, and form a plurality of hermetic windows 1230 from the cavities. Eventually, an unbound part of the packaging wafer 1210 is removed, and a wafer level package is formed. After wafer level testing, the wafer level package may be divided into a plurality of individual packages for electronic products.

As described above, the invention provides a pre-cutting process to form a plurality of trenches on the packaging wafer that may simplify the cutting process without damaging devices after the packaging wafer is bonded to the element wafer. Moreover, the wafer level package formed after the bonding may undergo a test before being dividing into individual packages. The sizes of the individual packages are similar to those of bare dies and have a tendency towards miniaturization of electronic products. In addition, the method of the invention may apply to batch production.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of wafer level packaging and cutting, comprising:
providing a packaging wafer, the packaging wafer comprising a plurality of cavities on an upper surface thereof;
performing a pre-cutting process upon the upper surface of the packaging wafer, and forming a plurality of trenches between the cavities and a plurality of partitions between the trenches and the cavities, wherein the packaging wafer has a thickness greater than a depth of the trenches;
providing an element wafer, the element wafer comprising a plurality of devices and a plurality of bonding pads on a surface of the element wafer;
bonding the partitions of the packaging wafer to the element wafer; and
performing a cutting process along the trenches on a lower surface of the packaging wafer, thereafter removing an unbound part of the packaging wafer to expose the bonding pads of the element wafer, and consequently forming a wafer level package.

2. The method of claim 1, wherein the packaging wafer comprises a transparent substrate and a pattern, which defines the cavities, disposed on an upper surface of the transparent substrate.

3. The method of claim 2, wherein the transparent substrate comprises glass, quartz, or plastic.

4. The method of claim 1, wherein bonding the packaging wafer and the element wafer forms a hermetical window from each cavity.

5. The method of claim 1, wherein the pre-cutting process is a wet wafer-cutting process.

6. The method of claim 1, wherein the pre-cutting process is a dry wafer-cutting process.

7. The method of claim 1, wherein the devices are optical devices.

8. The method of claim 1, wherein the devices are micro electromechanical systems (MEMS) devices.

9. The method of claim 1, wherein the partitions of the packaging wafer are bonded to the element wafer by a binder.

10. The method of claim 9, wherein the binder comprises a glass frit or a polymer glue.

11. The method of claim 1, wherein the partitions of the packaging wafer are bonded to the element wafer by anodic bonding or fusion bonding.

12. The method of claim 1, further comprising performing a wafer level testing after the bonding pads of the element wafer are exposed.

13. The method of claim 12, wherein the wafer level package is divided into a plurality of individual packages after the wafer level testing.

14. A method of wafer level packaging and cutting, comprising:
providing a packaging wafer, the packaging wafer comprising a transparent substrate, a pattern disposed on an upper surface of the transparent substrate, and a plurality of cavities, which are defined by the pattern, disposed on the upper surface of the transparent substrate;
performing a pre-cutting process upon an upper surface of the packaging wafer, and forming a plurality of trenches between the cavities and a plurality of partitions between the trenches and the cavities, wherein the packaging wafer has a thickness greater than a depth of the trenches;
providing an element wafer, the element wafer comprising a plurality of devices and a plurality of bonding pads on a surface of the element wafer;
aligning the packaging wafer and the element wafer, the cavities of the packaging wafer corresponding to the devices of the element wafer;
performing a hermetical bonding process in which the partitions of the packaging wafer are bonded to the element wafer;
performing a cutting process along the trenches on a lower surface of the packaging wafer, thereafter removing an unbound part of the packaging wafer, and consequently forming a wafer level package; and
dividing the wafer level package into a plurality of individual packages.

15. The method of claim 14, wherein the transparent substrate comprises glass, quartz or plastic.

16. The method of claim 14, wherein the pre-cutting process is a wet wafer-cutting process.

17. The method of claim 14, wherein the pre-cutting process is a dry wafer-cutting process.

18. The method of claim 14, wherein the devices of the element wafer are optical devices.

19. The method of claim 14, wherein the devices of the element wafer are micro electromechanical systems (MEMS) devices.

20. The method of claim 14, wherein the partitions of the packaging wafer are bonded to the element wafer by a binder.

21. The method of claim 20, wherein the binder comprises a glass frit or a polymer glue.

22. The method of claim 14, wherein the partitions have a thickness greater than that of the pattern.

23. The method of claim 22, wherein the partitions of the packaging wafer are bonded to the element wafer by anodic bonding or fusion bonding.

24. The method of claim 14, further comprising performing a wafer level testing after the bonding pads of the packaging wafer are exposed.
